(19) United States
(12) Patent Application Publication
(10) Pub. No.: US 2025/0327177 A1
(43) Pub. Date: Oct. 23, 2025

(54) REAGENT CARTRIDGE FOR SUBLIMATION AND REACTOR APPARATUS

(71) Applicant: CANATU FINLAND OY, Vantaa (FI)

(72) Inventors: Taneli JUNTUNEN, Vantaa (FI); Wojciech GLAZEK, Vantaa (FI); Olivier REYNAUD, Vantaa (FI)

(21) Appl. No.: 18/866,755

(22) PCT Filed: Jun. 1, 2023
(86) PCT No.: PCT/FI2023/050308

§ 371 Date: Nov. 18, 2024

(30) Foreign Application Priority Data
Jun. 3, 2022 (FI) 20225491

(51) Int. Cl. C23C 16/448; C01B 32/15; C23C 16/44

(52) U.S. Cl. CPC C23C 16/4481; C01B 32/15; C23C 16/4418

(57) ABSTRACT

A reagent cartridge for sublimation of a solid reagent includes a reagent chamber for holding the solid reagent and at least one pressure sensor for measuring pressure inside the reagent cartridge.

### FIELD OF TECHNOLOGY

This disclosure concerns chemical reactors and parts therefor. In particular, this disclosure concerns sublimation of solid reagents to form reagent gases to be used in chemical reactors, e.g., flow reactors.

### BACKGROUND

In flow reactors configured for floating-catalyst chemical vapor deposition (FCCVD) of carbon-based high-aspect-ratio molecular structures (HARMSs), such as carbon nanotubes, e.g., single-walled carbon nanotubes and/or multi-walled carbon nanotubes; carbon nanobuds; and/or graphene nanoribbons, ferrocene is commonly used as a precursor for in-situ formation of iron-containing catalyst nanoparticles that promote the formation of the HARMSs.

Generally, accurate control of reagent concentrations during chemical reactions is of utmost importance. For example, in case of FCCVD of carbon-based HARMSs, the mass inflow rate of ferrocene gas formed by sublimation of solid ferrocene must be precisely controlled for forming catalyst nanoparticles with strict target property ranges. Although various solutions have been devised for controlling the sublimation of solid reagents, certain factors, such as the uneven heating of solid reagents and the formation of blockages by condensation or deposition within a reactor, may result in variations in the reagent outflow rates from reagent cartridges used for reagent sublimation.

In light of the above, it may be desirable to develop new solutions related to controlling the sublimation of solid reagents.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

According to a first aspect, a reagent cartridge for sublimation of a solid reagent to form reagent gas and for mixing the reagent gas with flowing carrier gas to form a reagent-carrier gas mixture is provided. The reagent cartridge comprises a reagent chamber for holding the solid reagent and at least one pressure sensor for measuring pressure inside the reagent cartridge.

In an embodiment of the first aspect, the reagent cartridge is in accordance with the third aspect or any embodiment thereof.

According to a second aspect, a reactor apparatus comprising a reagent cartridge holder configured to hold a reagent cartridge according to the first aspect during operation of the reactor apparatus is provided. The reactor apparatus is configured to receive from the at least one pressure sensor of the reagent cartridge at least one cartridge pressure reading indicative of pressure inside the reagent cartridge.

In an embodiment of the second aspect, the reagent cartridge is in accordance with the fourth aspect or any embodiment thereof.

According to a third aspect, a reagent cartridge for sublimation of a solid reagent to form reagent gas and for mixing the reagent gas with flowing carrier gas to form a reagent-carrier gas mixture is provided. The reagent cartridge comprises a reagent chamber for holding the solid reagent, a gas injection chamber upstream from the reagent chamber for injecting carrier gas into the reagent cartridge, a first temperature sensor configured to measure temperature inside the reagent chamber, and a second temperature sensor configured to measure temperature inside the gas injection chamber.

In an embodiment of the third aspect, the reagent cartridge is in accordance with the first aspect or any embodiment thereof.

According to a fourth aspect, a reactor apparatus comprising a reagent cartridge holder configured to hold a reagent cartridge according to the third aspect during operation of the reactor apparatus is provided. The reactor apparatus is configured to receive from the first temperature sensor a first temperature reading indicative of temperature inside the reagent cartridge and from the second temperature sensor a second temperature reading indicative of temperature inside the gas injection chamber.

In an embodiment of the fourth aspect, the reagent cartridge is in accordance with the second aspect or any embodiment thereof.

### BRIEF DESCRIPTION OF THE DRAWINGS

The present disclosure will be better understood from the following detailed description read in light of the accompanying drawings, wherein:

FIG. 1 shows a reagent cartridge,

FIG. 2 depicts a reactor apparatus, and

FIG. 3 illustrates a temperature control algorithm.

Unless specifically stated to the contrary, any drawing of the aforementioned drawings may be not drawn to scale such that any element in said drawing may be drawn with inaccurate proportions with respect to other elements in said drawing in order to emphasize certain structural aspects of the embodiment of said drawing.

Moreover, corresponding elements in the embodiments of any two drawings of the aforementioned drawings may be disproportionate to each other in said two drawings in order to emphasize certain structural aspects of the embodiments of said two drawings.

### DETAILED DESCRIPTION

Concerning reagent cartridges and reactor apparatuses discussed in this detailed description, the following shall be noted.

Throughout this specification, a “high-aspect-ratio molecular structure” or a “HARMS” may refer to a nanostructure, i.e., a structure with one or more characteristic dimensions in nanoscopic scale, e.g., greater than or equal to 0.1 nanometers (nm) and less than or equal to about 100 nm. Additionally or alternatively, a HARMS may refer to a structure having dimensions in two perpendicular directions with significantly different orders of magnitude. For example, a HARMS may have a length which is tens or hundreds of times higher than its thickness and/or width. Examples of HARMSs include nanotubes, e.g., carbon nanotubes and boron nitride nanotubes; nanoribbons, e.g., graphene nanoribbons, graphite nanoribbons, and boron nitride nanoribbons; nanowires, e.g., tungsten nanowires, copper nanowires, aluminum nanowires, nickel nanowires, and silver nanowires; nanofibers, e.g., carbon nanofibers and silicon carbide nanofibers; and nanoplatelets, e.g., graphene nanoplatelets, borophene nanoplatelets, and boron nitride nanoplatelets.

Further, a “carbon-based” HARMS may refer to a HARMS consisting primarily of carbon (C). Additionally, or alternatively, a carbon-based HARMS may refer to a HARMS comprising at least 50 atomic percent (at. %), or at least 60 at. %, or at least 70 at. %, or at least 80 at. %, or at least 90 at. %, or at least 95 at. % of carbon. Generally, carbon-based HARMSs may be doped with non-carbon dopants, for example, to alter their electrical and/or thermal properties. Examples of carbon-based HARMSs include carbon nanotubes, carbon nanobuds, graphene nanoribbons, carbon nanofibers, graphene nano-platelets, and combinations thereof.

In this disclosure, a “high-aspect-ratio molecular structure network” or “HARMS network” may refer to a plurality of mutually interconnected HARMSs. Generally, a HARMS network may form a solid and/or monolithic material at a macroscopic scale, wherein individual HARMSs are non-oriented, i.e., substantially randomly oriented or randomly oriented, or oriented. Typically, a HARMS network may be arranged in various macroscopic forms, for example, as films, which may or may not be optically transparent and/or possess high electrical conductivity.

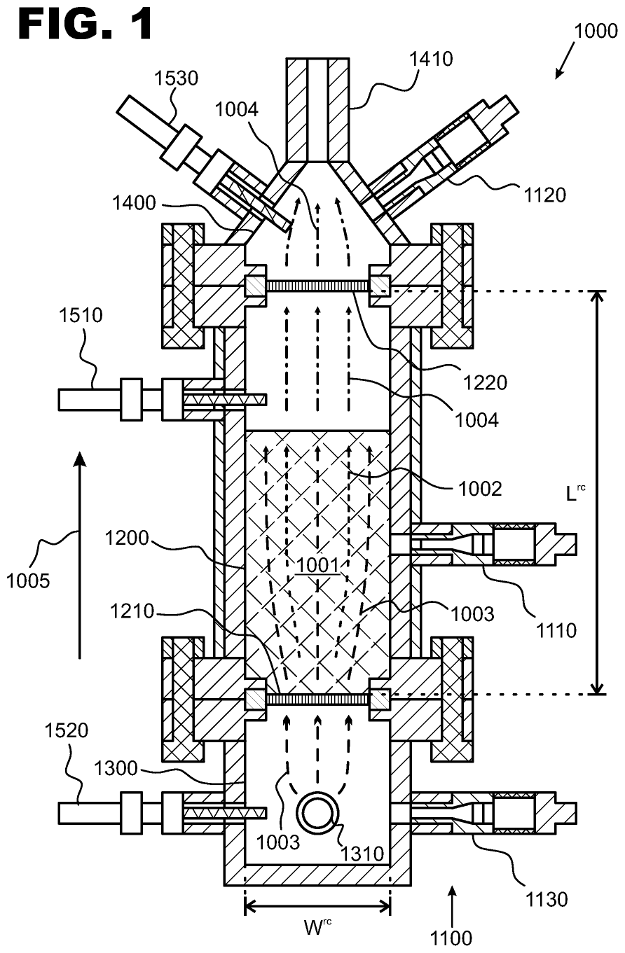

FIG. 1 depicts a schematic cross-sectional view of a reagent cartridge 1000 for sublimation of a solid reagent 1001 to form reagent gas 1002 and for mixing the reagent gas 1002 with flowing carrier gas 1003 to form a reagent-carrier gas mixture 1004 according to an embodiment.

The reagent cartridge 1000 of the embodiment of FIG. 1 is in accordance with both the first aspect and the third aspect. In other embodiments, a reagent cartridge may be in accordance with the first aspect and/or the third aspect.

The reagent cartridge 1000 of the embodiment of FIG. 1 is configured for sublimation of the solid reagent 1001. In other embodiments according to the first aspect and/or the third aspect, a reagent cartridge for sublimation of a solid reagent may be suitable or configured for sublimation of a solid reagent.

In the embodiment of FIG. 1, the reagent cartridge 1000 comprises a reagent chamber 1200 for holding the solid reagent 1001 and at least one pressure sensor 1100 for measuring pressure inside the reagent cartridge 1000. Generally, a reagent cartridge comprising at least one pressure sensor for measuring pressure inside the reagent cartridge may facilitate maintaining the pressure in the vicinity of a solid reagent held within said reagent cartridge within a pre-defined pressure range, which may, in turn, enable limiting variations in reagent output mass flow rate from the reagent cartridge. Additionally or alternatively, a reagent cartridge comprising at least one pressure sensor for measuring pressure inside the reagent cartridge may enable compensating for the effect of changes in reactor pressure to pressure inside the reagent cartridge. Additionally or alternatively, a reagent cartridge comprising at least one pressure sensor for measuring pressure inside the reagent cartridge may enable detecting formation of a blockage downstream from the reagent cartridge. In other embodiments according to the third aspect, a reagent cartridge may or may not comprise at least one pressure sensor for measuring pressure inside the reagent cartridge.

In the embodiment of FIG. 1, the at least one pressure sensor 1100 comprises a first pressure sensor 1110 configured to measure pressure inside the reagent chamber 1200. Generally, at least one pressure sensor of a reagent cartridge comprising a first pressure sensor configured to measure pressure inside a reagent chamber for holding a solid reagent may increase accuracy or trueness of pressure readings interpreted as relating to pressure in the vicinity of the solid reagent. In other embodiments according to the first aspect and/or the third aspect, at least one pressure sensor of a reagent cartridge may or may not comprise a first pressure sensor configured to measure pressure inside a reagent chamber of said reagent cartridge.

The reagent cartridge 1000 comprises a gas ejection chamber 1400 downstream from the reagent chamber 1200 for ejecting the reagent-carrier gas mixture 1004 out of the reagent cartridge 1000, and the at least one pressure sensor 1100 comprises a second pressure sensor 1120 configured to measure pressure inside the gas ejection chamber 1400. Generally, at least one pressure sensor of a reagent cartridge comprising a second pressure sensor configured to measure pressure inside a gas ejection chamber for ejecting a reagent-carrier gas mixture out of the reagent cartridge may enable increasing validity of blockage detection algorithms based on detecting an increase in at least one cartridge pressure reading indicative of pressure inside the reagent cartridge. In other embodiments according to the first aspect and/or the third aspect, at least one pressure sensor of a reagent cartridge may or may not comprise a second pressure sensor configured to measure pressure inside a gas ejection chamber for ejecting a reagent-carrier gas mixture out of the reagent cartridge.

In the embodiment of FIG. 1, the reagent cartridge 1000 comprises, in addition to the reagent chamber 1200 for holding the solid reagent 1001, a gas injection chamber 1300 upstream from the reagent chamber 1200 for injecting carrier gas 1003 into the reagent cartridge 1000, a first temperature sensor 1510 configured to measure temperature inside the reagent chamber 1200, and a second temperature sensor 1520 configured to measure temperature inside the gas injection chamber 1300.

Generally, a reagent cartridge comprising a first temperature sensor configured to measure temperature inside a reagent chamber, and a second temperature sensor configured to measure temperature inside a gas injection chamber may enable maintaining a solid reagent more precisely at a pre-determined solid reagent temperature throughout the extent of a reagent chamber. Additionally or alternatively, when a reagent cartridge comprises at least one pressure sensor for measuring pressure inside the reagent cartridge, a reagent cartridge comprising a first temperature sensor configured to measure temperature inside a reagent chamber and a second temperature sensor configured to measure temperature inside a gas injection chamber may enable controlling the thermodynamic state of a solid reagent more accurately throughout the extent of a reagent chamber, which may, in turn, enable forming a reagent-carrier gas mixture with more well-defined properties, and/or enable adjusting carrier gas mass flow rate more accurately to maintain a pre-determined reagent output mass flow rate.

In other embodiments according to the first aspect, a reagent cartridge may or may not comprise a gas injection chamber upstream from a reagent chamber for injecting carrier gas into the reagent cartridge, a first temperature sensor configured to measure temperature inside the reagent chamber, and/or a second temperature sensor configured to measure temperature inside the gas injection chamber.

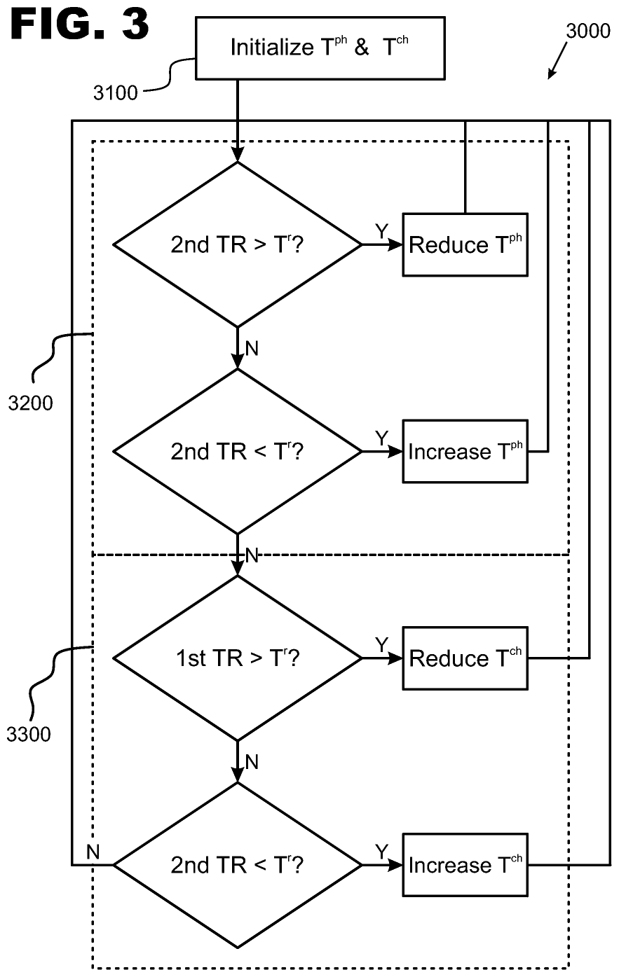

The reagent cartridge 1000 of the embodiment of FIG. 3 further comprises a third temperature sensor 1530 configured to measure temperature inside the gas ejection chamber 1400. In other embodiments according to the first aspect and/or the third aspect, a reagent cartridge may or may not comprise such a third temperature sensor.

In the embodiment of FIG. 1, each of the first temperature sensor 1510, the second temperature sensor 1520, and the third temperature sensor 1530 comprises a resistance thermometer element, specifically a platinum resistance thermometer (PRI) element, such as a Pt100 resistance thermometer element, and each of the first temperature sensor 1510, the second temperature sensor 1520, and the third temperature sensor 1530 is configured for 3-wire or 4-wire electrical output connection according to the IEC 60751:2008 standard. In other embodiments according to the first aspect and/or the third aspect, one or more of a first temperature sensor, a second temperature sensor, and a third temperature sensor may or may not comprise one or more resistance thermometer elements, such as one or more PRTs, e.g., one or more Pt100 resistance thermometer elements or one or more Pt1000 resistance thermometer elements. In other embodiments according to the first aspect and/or the third aspect, wherein at least one of a first temperature sensor, a second temperature sensor, and a third temperature sensor comprises a PRT element, at least part of said at least one sensors may or may not be configured for 3-wire or 4-wire electrical output connection according to the IEC 60751:2008 standard.

In the embodiment of FIG. 1, the at least one pressure sensor 1100 further comprises a third pressure sensor 1130 configured to measure pressure inside the gas injection chamber 1300. In other embodiments according to the first aspect and/or the third aspect, at least one pressure sensor of a reagent cartridge may or may not comprise such a third pressure sensor.

Each of the at least one pressure sensor 1100, i.e., the first pressure sensor 1110, the second pressure sensor 1120, and the third pressure sensor 1130 comprises a flush-mounted diaphragm. In other embodiments according to the first aspect and/or the third aspect, one or more, for example, each, of at least one pressure sensor may comprise a flush-mounted diaphragm.

In the embodiment of FIG. 1, the reagent chamber 1200 comprises solid ferrocene (Fe(C₅H₂)₂). In other embodiments according to the first aspect and/or the third aspect, a reagent chamber of a reagent cartridge may or may not comprise any suitable sublimatable solid reagent, such as solid ferrocene (Fe(C₅H₂)₂).

In the embodiment of FIG. 1, the reagent chamber 1200 and the gas injection chamber 1300 are separated from one another by a sintered filter 1210, i.e., a porous disk formed of stainless steel configured to block passage of microparticles, while the reagent chamber 1200 and the gas ejection chamber 1400 are separated from one another by a perforated wall, particularly a stainless steel mesh screen 1220. In other embodiments according to the first aspect and/or the third aspect, a reagent chamber may be separated from a gas injection chamber and/or a gas ejection chamber in any suitable manner, for example, by a filter, e.g., a sintered filter, and/or a perforated wall, e.g., a mesh screen. In such other embodiments, any such separating structures may be formed of any suitable material(s), for example, stainless steel and/or titanium.

The reagent chamber 1200 of the embodiment of FIG. 1 has a reagent chamber width (W^{rc}), measured perpendicular to a carrier gas flow direction 1005 inside the reagent chamber 1200, of approximately 5 centimeters (cm). In other embodiments according to the first aspect and/or the third aspect, a reagent chamber may have any suitable reagent chamber width measured perpendicular to a carrier gas flow direction inside the reagent chamber, for example, a reagent chamber width greater than or equal to 1 cm, or to 2 cm, or to 3 cm, or to 4 cm and/or less than or equal to 20 cm, or to 15 cm, or to 10 cm, or to 7 cm.

The reagent chamber 1200 of the embodiment of FIG. 1 has a reagent chamber length (L^{rc}), measured parallel to the carrier gas flow direction 1005 inside the reagent chamber 1200, of approximately 15 centimeters (cm). In other embodiments according to the first aspect and/or the third aspect, a reagent chamber may have any suitable reagent chamber length measured parallel to a carrier gas flow direction inside the reagent chamber, for example, a reagent chamber length greater than or equal to 3 cm, or to 5 cm, or to 8 cm, or to 10 cm, or to 12 cm and/or less than or equal to 50 cm, or to 40 cm, or to 30 cm, or to 25 cm, or to 20 cm.

In the embodiment of FIG. 1, the reagent cartridge 1000 is configured to pass the carrier gas 1003 through the reagent chamber 1200 to bring about fluidization of granular material arranged in the reagent chamber 1200. Generally, a reagent cartridge being configured to pass carrier gas through a reagent chamber to bring about fluidization of granular material arranged in the reagent chamber may facilitate reducing local temperature differences inside the reagent chamber. In other embodiments according to the first aspect and/or the third aspect, a reagent cartridge may or may not be configured in such a manner.

The reagent cartridge 1000 of the embodiment of FIG. 1 comprises a carrier gas inlet 1310 for feeding carrier gas 1003 into the reagent cartridge 1000 and a reagent-carrier gas mixture outlet 1410 for discharging reagent-carrier gas mixture 1004 from the reagent cartridge 1000. In other embodiments according to the first aspect and/or the third aspect, a reagent cartridge may comprise any suitable type(s) of carrier gas inlet(s) and reagent-carrier gas mixture outlet(s).

It is to be understood that the embodiments of the first aspect and/or the third aspect described above may be used in combination with each other. Several of the embodiments may be combined together to form a further embodiment of the first aspect and/or the third aspect.

Above, mainly features of reagent cartridges are discussed. In the following, more emphasis will lie on features of reactor apparatuses. What is said above about the ways of implementation, definitions, details, and advantages related to the reagent cartridges applies, mutatis mutandis, to the reactor apparatuses discussed below. The same applies vice versa.

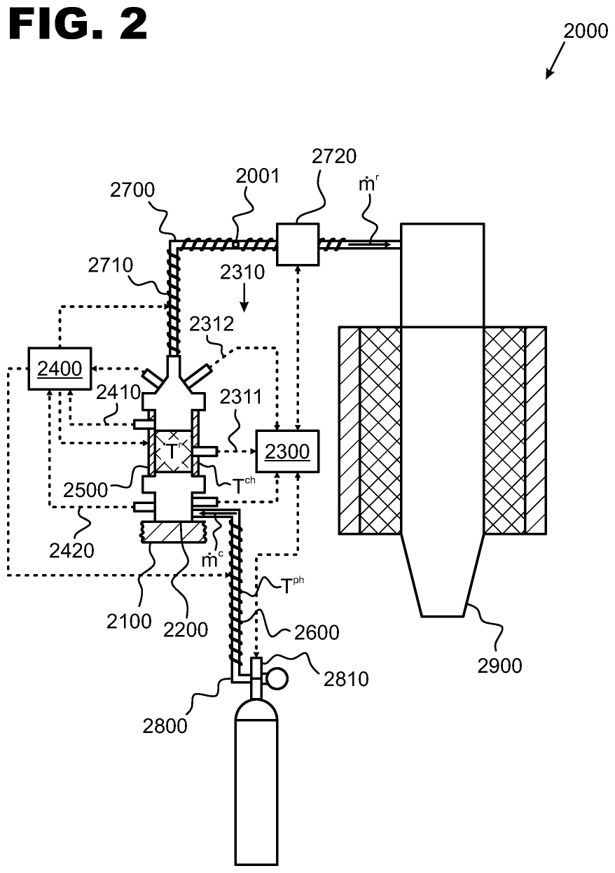

FIG. 2 schematically illustrates a reactor apparatus 2000 according to an embodiment.

The reactor apparatus 2000 of the embodiment of FIG. 2 is in accordance with both the second aspect and the fourth aspect. In other embodiments, a reactor apparatus may be in accordance with the second aspect and/or the fourth aspect.

In the embodiment of FIG. 2, the reactor apparatus 2000 comprising a reagent cartridge holder 2100 configured to hold a reagent cartridge 2200 according to the first aspect and the third aspect during operation of the reactor apparatus 2000. The reactor apparatus 2000 further comprises a reagent cartridge 2200 according to the first aspect and the third aspect held by the reagent cartridge holder 2100. In other embodiments in accordance with the second aspect and/or the fourth aspect, a reactor apparatus may comprise a reagent cartridge holder for holding or configured to hold a reagent cartridge according to the first aspect and/or third aspect, respectively, during operation of the reactor apparatus. In such embodiments, said reactor apparatus may or may not comprise said reagent cartridge.

The reagent cartridge 2200 of the embodiment of FIG. 2 may be identical to the reagent cartridge 1000 of the embodiment of FIG. 1. In other embodiments in accordance with the second aspect and/or the fourth aspect, any suitable reagent cartridge, for example, a reagent cartridge different, similar, or identical to the reagent cartridge 1000 of the embodiment of FIG. 1, may be used.

The reactor apparatus 2000 of the embodiment of FIG. 2 is configured to receive from the at least one pressure sensor 1100 of the reagent cartridge 2200 at least one cartridge pressure reading 2310 indicative of pressure inside the reagent cartridge 2200. In other embodiments according to the fourth aspect, a reactor apparatus may or may not be configured to receive from at least one pressure sensor of a reagent cartridge at least one cartridge pressure reading indicative of pressure inside the reagent cartridge.

In the embodiment of FIG. 2, the reactor apparatus 2000 is configured for producing carbon-based HARMSs, particularly carbon nanobuds, by floating-catalyst chemical vapor deposition (FCCVD). In other embodiments in accordance with the second aspect and/or the fourth aspect, a reactor apparatus may or may not be configured for producing carbon-based HARMSs, such as carbon nanotubes, e.g., single-walled carbon nanotubes and/or multi-walled carbon nanotubes; carbon nanobuds; and/or graphene nanoribbons, for example, by FCCVD.

Even if not explicitly shown in FIG. 2, the reactor apparatus 2000 of the embodiment of FIG. 2 may comprise any features and/or elements necessary or beneficial for producing carbon-based HARMSs, for example, a carbon source reservoir, which may be provided with one or more heaters and/or pressure sensors; a carbon source conduit, which may be provided with one or more heaters and/or one or more flow controllers, and the like.

The reactor apparatus 2000 of the embodiment of FIG. 2 may be implemented as a continuous-flow reactor apparatus. In other embodiments in accordance with the second aspect and/or the fourth aspect, a reactor apparatus may or may not be implemented as a continuous-flow reactor apparatus. For example, in some such embodiments, a reactor apparatus may be implemented as a batch-type reactor apparatus.

In the embodiment of FIG. 2, the reactor apparatus 2000 comprises a flow reactor 2900. In other embodiments in accordance with the second aspect and/or the fourth aspect, a reactor apparatus may comprise any suitable type(s) of reactor(s), for example, one or more flow reactors.

Herein, a “flow reactor” may refer to a chemical reactor into which one or more reagents, for example, one or more catalyst particle precursors and/or one or more reactants, such as a carbon source, and/or one or more auxiliary substances, e.g., catalysts and/or growth promoters, such as sulfur (S); phosphorus (P); nitrogen (N); one or more sulfur-containing compounds, e.g., hydrogen sulfide (H₂S), carbon bisulfide (CS₂), and/or thiophene (C₄H₄S); one or more phosphorus-containing compounds, e.g., phosphane (PH₃); one or more nitrogen-containing compounds, e.g., ammonia (NH₃) and/or nitric oxide (NO); and/or redox agents, e.g., oxygen (O₂), water (H₂O), carbon dioxide (CO₂), and/or hydrogen (H₂), are introduced, for example, continuously introduced, and wherefrom one or more products are collected, for example, continuously collected. Additionally or alternatively, a flow reactor may refer to a reactor through which one or more reagents pass and wherein catalysis is in progress. Typically, a flow reactor may be formed of any suitable material(s), for example, stainless steel, fused silica, or fused quartz.

In the embodiment of FIG. 2, the reactor apparatus 2000 comprises a carrier gas conduit 2800 for providing a flow of carrier gas through the reagent cartridge 2200 and a reagent gas conduit 2700 for directing reagent-carrier gas mixture formed in the reagent cartridge 2200 into the flow reactor 2900. In other embodiments in accordance with the second aspect and/or the fourth aspect, a flow of carrier gas may be provided through a reagent cartridge by any suitable means, e.g., via a carrier gas conduit, and reagent-carrier gas mixture formed in the reagent cartridge may be directed to any suitable destination, for example, a chemical reactor, by any suitable means, e.g., via a reagent gas conduit.

The reagent cartridge 2200 of the embodiment of FIG. 2 is configured to form a reagent-carrier gas mixture comprising ferrocene (Fe(C₅H₂)₂) gas as a reagent gas and nitrogen (N₂) gas as the carrier gas. In other embodiments in accordance with the second aspect and/or the fourth aspect, any suitable reagent gas(es), such as one or more catalyst particle precursors (e.g., iron-containing organometallic or metalorganic compounds, such as ferrocene (Fe(C₅H₂)₂), iron pentacarbonyl (Fe(CO)₅), and/or iron(II)phthalocyanine (C₃₂H₁₆FeN₈); and/or one or more nickel-containing organometallic or metalorganic compounds, such as nickelocene (Ni(C₅H₅)₂); and/or one or more cobalt-containing organometallic or metalorganic compounds, such as cobaltocene (Co(C₅H₅)₂)), and carrier gas(es)), such as argon (Ar), helium (He), nitrogen (N₂), carbon monoxide (CO), and/or hydrogen (H₂), may be used.

In the embodiment of FIG. 2, the reactor apparatus 2000 is configured to decompose the reagent gas to form catalyst particles, particularly iron-containing nanoparticles. In other embodiments in accordance with the second aspect and/or the fourth aspect, a reactor apparatus may or may not be configured in such a manner.

Throughout this specification, a “catalyst particle” may refer to a particulate piece of matter suitable for increasing the rate of a reaction via catalysis. Additionally or alternatively, a catalyst particle may refer to a particle suitable for heterogenous catalysis. Additionally or alternatively, a catalyst particle may refer to a piece of particulate catalyst material suitable for catalysis of production of carbon-based HARMSs, for example, by chemical vapor deposition, e.g., floating-catalyst chemical vapor deposition (FCCVD). Generally, a catalyst particle, may comprise, consist substantially of, or consist of one or more transition metals, such as iron (Fe), cobalt (Co), and/or nickel (Ni). Typically, a catalyst particle may have any suitable diameter, for example, a diameter in a range from 0.1 nm to 300 nm, or from 1 nm to 200 nm, or from 5 nm to 100 nm, or from 10 nm to 50 nm.

In the embodiment of FIG. 2, the reactor apparatus 2000 is configured to adjust carrier gas mass flow rate (\dot{m}^{c}) based on at least part of the at least one cartridge pressure reading 2310 to maintain a pre-determined reagent output mass flow rate (\dot{m}^{r}) from the reagent cartridge 2200. Generally, a reactor apparatus being configured to adjust carrier gas mass flow rate based on at least part of at least one cartridge pressure reading to maintain a pre-determined reagent output mass flow rate from a reagent cartridge may facilitate feeding a constant amount of reagent gas into a reactor apparatus. In other embodiments in accordance with the second aspect and/or the fourth aspect, a reactor apparatus may or may not be configured to adjust carrier gas mass flow rate based on at least part of at least one cartridge pressure reading to maintain a pre-determined reagent output mass flow rate from a reagent cartridge.

A reactor apparatus being “configured to” perform a process may refer to capability of and suitability of said reactor apparatus for such process. This may be achieved in various ways. For example, a reactor apparatus, or a control unit thereof, may comprise at least one processor and at least one memory coupled to the at least one processor, the memory storing program code instructions which, when executed on said at least one processor, cause the processor to perform the process(es) at issue. Additionally or alternatively, any functionally described features of a reactor apparatus may be performed, at least in part, by one or more hardware logic components. For example, and without limitation, illustrative types of suitable hardware logic components include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), and the like. A reactor apparatus may generally be operated in accordance with any appropriate principles and by means of any appropriate circuitry and/or signals known in the art.

In the embodiment of FIG. 2, the reagent cartridge 2200 comprises solid ferrocene as a solid reagent, and an increase in pressure reduces the rate of sublimation of ferrocene. Consequently, the reactor apparatus 2000 of the embodiment of FIG. 2 is configured to increase \dot{m}^{c} in response to an increase in pressure inside the reagent cartridge 2200 and to decrease \dot{m}^{c} in response to a decrease in pressure inside the reagent cartridge 2200. In other embodiments in accordance with the second aspect and/or the fourth aspect, wherein a reactor apparatus is configured to adjust carrier gas mass flow rate based on at least part of at least one cartridge pressure reading to maintain a pre-determined reagent output mass flow rate from a reagent cartridge, the reactor apparatus may be configured to increase or decrease the carrier gas mass flow rate in response to an increase in the at least part of at least one cartridge pressure reading.

The reactor apparatus 2000 of the embodiment of FIG. 2 is specifically configured to adjust \dot{m}^{c} based on a first pressure reading 2311 indicative of pressure inside the reagent chamber 1200 of the reagent cartridge 2200. Generally, a reactor apparatus being configured to adjust a carrier gas mass flow rate based on at least a first pressure reading indicative of pressure inside a reagent chamber of a reagent cartridge may increase accuracy or trueness of pressure readings interpreted as relating to pressure in the vicinity of a solid reagent, which may, in turn, enable more accurate control of carrier gas mass flow rate.

In other embodiments in accordance with the second aspect and/or the fourth aspect, wherein a reactor apparatus is configured to adjust carrier gas mass flow rate based on at least part of at least one cartridge pressure reading to maintain a pre-determined reagent output mass flow rate from a reagent cartridge, the reactor apparatus may be configured to adjust the carrier gas mass flow rate based on any one or more of the at least one cartridge pressure reading, for example, at least a first pressure reading indicative of pressure inside a reagent chamber of the reagent cartridge.

In the embodiment of FIG. 2, the reactor apparatus 2000 is also configured to detect formation of a blockage 2001 downstream from the reagent cartridge 2200 based on at least part of the at least one cartridge pressure reading 2310. Such blockages may typically be formed downstream from a reagent cartridge due to condensation or deposition of reagent gas, which may result, for example, from insufficient heating of a reagent gas conduit used to direct reagent-carrier gas mixture from a reagent cartridge towards a reactor of a reactor apparatus, and the formation of blockage may commonly be detected based on a relatively sudden increase in the at least part of the at least one cartridge pressure reading. Generally, a reactor apparatus being configured to detect formation of a blockage downstream from a reagent cartridge based on at least part of the at least one cartridge pressure reading may facilitate maintenance of the reactor apparatus. In other embodiments in accordance with the second aspect and/or the fourth aspect, a reactor apparatus may or may not be configured to detect formation of a blockage downstream from a reagent cartridge based on at least part of the at least one cartridge pressure reading.

The reactor apparatus 2000 of the embodiment of FIG. 2 is specifically configured to detect the formation of the blockage 2001 based on a second pressure reading 2312 indicative of pressure inside a gas ejection chamber of the reagent cartridge 2200. Generally, a reactor apparatus being configured to detect formation of a blockage based on at least a second pressure reading indicative of pressure inside a gas ejection chamber of a reagent cartridge may increase the accuracy or trueness of such detection, for example, by reducing the probability of false positive detection results. In other embodiments in accordance with the second aspect and/or the fourth aspect, wherein a reactor apparatus is configured to detect formation of a blockage downstream from a reagent cartridge based on at least part of at least one cartridge pressure reading, the reactor apparatus may or may not be configured to detect formation of the blockage based on at least a second pressure reading indicative of pressure inside a gas ejection chamber of the reagent cartridge.

The reactor apparatus 2000 comprises a reagent conduit mass flow meter 2720 for measuring mass flow rate via the reagent gas conduit 2700; a carrier gas flow controller 2810 for controlling \dot{m}^{c}; and a pressure control unit 2300 operatively coupled with the at least one pressure sensor of the reagent cartridge 2200 for receiving the at least one cartridge pressure reading 2310 and with the reagent conduit mass flow meter 2720 as well as the carrier gas flow controller 2810 for adjusting \dot{m}^{c} based on \dot{m}^{r}. In other embodiments in accordance with the second aspect and/or the fourth aspect, a pressure control unit may or may not be operatively coupled with at least one pressure sensor, a reagent conduit mass flow meter, and a carrier gas flow controller in such a manner. For example, in some such embodiments, a pre-determined reagent output mass flow rate may be maintained by adjusting carrier gas mass flow rate based on at least one cartridge pressure reading and a known phenomenological model describing the relationship between the at least one cartridge pressure reading and reagent sublimation rate. In such case, a specific reagent conduit mass flow meter may be omitted.

In this specification, a “control unit” may refer to a device, e.g., an electronic device, having at least one specified function related to determining and/or influencing an operational condition, status, or parameter related to another device, unit, or element. A control unit may or may not form a part of a multifunctional control system.

Further, a control unit being “operatively coupled” with a device, unit, or element may refer to the control unit having at least one specified function related to determining and/or influencing an operational condition, status, or parameter related to said device, unit, or element.

In the embodiment of FIG. 2, the reactor apparatus 2000 may be further configured to compensate for changes in pressure inside the flow reactor 2900 to stabilize pressure inside the reagent cartridge the reagent cartridge 2200. In other embodiments in accordance with the second aspect and/or the fourth aspect, a reactor apparatus may or may not be configured in such a manner.

In the embodiment of FIG. 2, the reactor apparatus 2000 is further configured to receive from a first temperature sensor of the reagent cartridge 2200 a first temperature reading 2410 indicative of temperature inside the reagent chamber 1200 and from a second temperature sensor of the reagent cartridge 2200 a second temperature reading 2420 indicative of temperature inside the gas injection chamber 1300. In other embodiments in accordance with the second aspect and/or the fourth aspect, a reactor apparatus may or may not be configured to receive from a first temperature sensor a first temperature reading indicative of temperature inside a reagent chamber and from a second temperature sensor a second temperature reading indicative of temperature inside a gas injection chamber.

The reactor apparatus 2000 of the embodiment of FIG. 2 is configured to maintain a pre-determined solid reagent temperature (T^{r}) based on at least the first temperature reading 2410 and the second temperature reading 2420. Generally, a reactor apparatus being configured to maintain a pre-determined solid reagent temperature based on at least a first temperature reading and a second temperature reading may facilitate maintaining a narrower solid reagent temperature distribution throughout the extent of a reagent chamber. Additionally or alternatively, a reactor apparatus being configured to maintain a pre-determined solid reagent temperature based on at least a first temperature reading and a second temperature reading may enable mitigating or avoiding temporal solid reagent temperature fluctuations caused, for example, by lag in temperature control resulting from time-consuming heat transfer in a solid reagent. In other embodiments in accordance with the second aspect and/or the fourth aspect, wherein a reactor apparatus is configured to receive a first temperature reading indicative of temperature inside a reagent chamber and a second temperature reading indicative of temperature inside a gas injection chamber, the reactor apparatus may or may not be configured to maintain a pre-determined solid reagent temperature based on at least the first temperature reading and the second temperature reading.

In the embodiment of FIG. 2, the reactor apparatus 2000 comprises a cartridge heater 2500 for heating the reagent cartridge 2200 and a pre-heater 2600 for heating the carrier gas upstream of the reagent cartridge 2200. During operation of the reactor apparatus 2000, the reactor apparatus 2000 is configured to adjust pre-heater temperature (T^{ph}) based on a comparison between the pre-determined solid reagent temperature (T^{r}) and the second temperature reading 2420 and to adjust cartridge heater temperature (T^{ch}) based on a comparison between the solid reagent temperature (T^{r}) and the first temperature reading 2410. Generally, a reactor apparatus being configured to adjust pre-heater temperature based on a comparison between a pre-determined (target) solid reagent temperature and a second temperature reading and to adjust cartridge heater temperature based on a comparison between the solid reagent temperature and a first temperature reading may enable utilization of heat provided by a pre-heater to reduce solid reagent temperature variations throughout the extent of a reagent chamber. In other embodiments in accordance with the second aspect and/or the fourth aspect, a reactor apparatus may or may not be configured to adjust pre-heater temperature based on a comparison between a pre-determined (target) solid reagent temperature and a second temperature reading and/or to adjust cartridge heater temperature based on a comparison between the solid reagent temperature and a first temperature reading.

The reactor apparatus 2000 comprises a temperature control unit 2400 operatively coupled with the first temperature sensor and the second temperature sensor of the reagent cartridge 2200 for receiving the first temperature reading 2410 and the second temperature reading 2420, respectively, and further with the cartridge heater 2500 and the pre-heater 2600 for heating the reagent cartridge 2200 and the carrier gas 1003 upstream of the reagent cartridge 2200, respectively.

In the embodiment of FIG. 2, the reactor apparatus 2000 is configured to maintain the pre-determined solid reagent temperature (T^{r}) by utilization of closed-loop control, particularly multi-loop closed-loop control. Typically, closed-loop control may be achieved, for example, by utilization of proportional (P) control, which may optionally be supplemented with integral (I) and/or derivative (D) control terms. In other embodiments in accordance with the second aspect and/or the fourth aspect, a reactor apparatus may or may not be configured to maintain a pre-determined solid reagent temperature by utilization of closed-loop control, for example, multi-loop closed-loop control.

In the embodiment of FIG. 2, T^{r} may be approximately 35° C. In other embodiments in accordance with the second aspect and/or the fourth aspect, any suitable solid reagent temperature, for example, a solid reagent temperature in a range from 20° C. to 100° C., or from 25° C. to 80° C., or from 30° C. to 50° C., may be used.

The cartridge heater 2500 of the embodiment of FIG. 2 is implemented as an electric lateral heater, specifically as a silicone heating mat surrounding the reagent chamber of the reagent cartridge 2200. The cartridge heater 2500 may be fastened to the reagent cartridge 2200 using fastening means, such as an adhesive, whereby the cartridge heater 2500 may form a part of the reagent cartridge 2200. In other embodiments in accordance with the second aspect and/or the fourth aspect, a cartridge heater may be implemented in any suitable manner, for example, as an electric lateral heater, such as a heating mat surrounding a reagent chamber. In any embodiment according to the first aspect and/or the third aspect, a cartridge heater may be implemented as a part of a reagent cartridge.

The reactor apparatus 2000 of the embodiment of FIG. 2 further comprises a reagent conduit heater 2710, and the temperature control unit 2400 is operatively coupled with the reagent conduit heater 2710 for heating the reagent gas conduit 2700. In other embodiments in accordance with the second aspect and/or the fourth aspect, a reactor apparatus may or may not comprise a reagent conduit heater, and a temperature control unit may or may not be operatively coupled with the reagent conduit heater for heating a reagent gas conduit.

In the embodiment of FIG. 2, the temperature control unit 2400 is configured to maintain temperature of the reagent gas conduit 2700 at approximately 50° C. In other embodiments in accordance with the second aspect and/or the fourth aspect, wherein a temperature control unit is operatively coupled with a reagent conduit heater for heating a reagent gas conduit, any suitable reagent gas conduit temperature(s) may be used. For example, in some such embodiments, a temperature control unit may be configured to maintain temperature of a reagent gas conduit in a range from 30° C. to 200° C., or from 50° C. to 190° C., or from 100° C. to 180° C.

The reactor apparatus 2000 of the embodiment of FIG. 2 forms an example of a reactor apparatus comprising a reagent gas conduit for extracting reagent-carrier gas mixture from a reagent cartridge and a reagent conduit heater for heating the reagent gas conduit. In other embodiments in accordance with the second aspect and/or the fourth aspect, a reactor apparatus may or may not comprise a reagent gas conduit for extracting reagent-carrier gas mixture from a reagent cartridge and a reagent conduit heater for heating the reagent gas conduit.

FIG. 3 illustrates a simplified proportional closed-loop temperature control algorithm 3000 according to which a pre-determined T^{r} may be maintained by a reactor apparatus, such as the reactor apparatus 2000 of the embodiment of FIG. 2, based on a first temperature reading and a second temperature reading. Naturally, reactor apparatuses in accordance with the second and/or the fourth aspects may utilize any suitable temperature control algorithm(s), which may be identical, similar or different to the temperature control algorithm 3000 of FIG. 3.

The temperature control algorithm 3000 of FIG. 3 comprises an initialization step 3100 for initializing a pre-heater temperature (T^{ph}) and a cartridge heater temperature (T^{ch}), a pre-heater control step 3200, and a cartridge heater control step 3300.

During the pre-heater control step 3200, a second temperature reading indicative of temperature inside a gas injection chamber is compared with a pre-determined solid reagent temperature (T^{r}). On the one hand, if the second temperature reading is higher than T^{r}, T^{ph} is reduced and the temperature control algorithm 3000 returns to the beginning of the pre-heater control step 3200. On the other hand, if the second temperature reading is lower than T^{r}, T^{ph} is increased and the temperature control algorithm 3000 returns to the beginning of the pre-heater control step 3200.

During the cartridge heater control step 3300, a first temperature reading indicative of temperature inside a reagent chamber is compared with T^{r}. On the one hand, if the first temperature reading is higher than T^{r}, T^{ch} is reduced and the temperature control algorithm 3000 returns to the beginning of the pre-heater control step 3200. On the other hand, if the first temperature reading is lower than T^{r}, T^{ch} is increased and the temperature control algorithm 3000 returns to the beginning of the pre-heater control step 3200.

It is obvious to a person skilled in the art that with the advancement of technology, the basic idea of the invention may be implemented in various ways. The invention and its embodiments are thus not limited to the examples described above, instead they may vary within the scope of the claims.

It will be understood that any benefits and advantages described above may relate to one embodiment or may relate to several embodiments. The embodiments are not limited to those that solve any or all of the stated problems or those that have any or all of the stated benefits and advantages.

The term “comprising” is used in this specification to mean including the feature(s) or act(s) followed thereafter, without excluding the presence of one or more additional features or acts. It will further be understood that reference to ‘an’ item refers to one or more of those items.

REFERENCE SIGNS

| \dot{m}^{c} | carrier gas mass flow rate |
|---|---|
| \dot{m}^{r} | reagent output mass flow rate |
| T^{r} | solid reagent temperature |
| T^{ph} | pre-heater temperature |
| T^{ch} | cartridge heater temperature |
| W^{rc} | reagent chamber width |
| L^{rc} | reagent chamber length |
| 1000 | reagent cartridge |
| 1001 | solid reagent |
| 1002 | reagent gas |
| 1003 | carrier gas |
| 1004 | reagent-carrier gas mixture |
| 1005 | carrier gas flow direction |
| 1100 | at least one pressure sensor |
| 1110 | first pressure sensor |
| 1120 | second pressure sensor |
| 1130 | third pressure sensor |
| 1200 | reagent chamber |
| 1210 | sintered filter |
| 1220 | mesh screen |
| 1300 | gas injection chamber |
| 1310 | carrier gas inlet |
| 1400 | gas ejection chamber |
| 1410 | reagent-carrier gas mixture outlet |
| 1510 | first temperature sensor |
| 1520 | second temperature sensor |
| 1530 | third temperature sensor |
| 2000 | reactor apparatus |
| 2001 | blockage |
| 2100 | reagent cartridge holder |
| 2200 | reagent cartridge |
| 2300 | pressure control unit |
| 2310 | at least one cartridge pressure reading |
| 2311 | first pressure reading |
| 2312 | second pressure reading |
| 2400 | temperature control unit |
| 2410 | first temperature reading |
| 2420 | second temperature reading |
| 2500 | cartridge heater |
| 2600 | pre-heater |
| 2700 | reagent gas conduit |
| 2710 | reagent conduit heater |
| 2720 | reagent conduit mass flow meter |
| 2800 | carrier gas conduit |
| 2810 | carrier gas flow controller |
| 2900 | flow reactor |
| 3000 | temperature control algorithm |
| 3100 | initialization step |
| 3200 | pre-heater control step |
| 3300 | cartridge heater control step |

1.-14. (canceled)

15. A reagent cartridge for sublimation of a solid reagent to form reagent gas and for mixing the reagent gas with flowing carrier gas to form a reagent-carrier gas mixture, the reagent cartridge comprising a reagent chamber for holding the solid reagent and a gas ejection chamber downstream from the reagent chamber for ejecting the reagent-carrier gas mixture out of the reagent cartridge;
wherein the reagent cartridge comprises a first pressure sensor configured to measure pressure inside the reagent chamber and a second pressure sensor configured to measure pressure inside the gas ejection chamber.

16. The reagent cartridge according to claim 15, further comprising a gas injection chamber upstream from the reagent chamber for injecting carrier gas into the reagent cartridge, a first temperature sensor configured to measure temperature inside the reagent chamber, and a second temperature sensor configured to measure temperature inside the gas injection chamber.

17. A reactor apparatus comprising a reagent cartridge for holding a reagent cartridge according to claim 15, wherein during operation of the reactor apparatus, the reactor apparatus configured to receive from at least one pressure sensor of the reagent cartridge at least one cartridge pressure reading indicative of pressure inside the reagent cartridge.

18. The reactor apparatus according to claim 16, wherein the reactor apparatus is configured to adjust carrier gas mass flow rate, “m”⋅\hat{ }“c”, based on at least part of the at least one cartridge pressure reading to maintain a pre-determined reagent output mass flow rate, “m”⋅\hat{ }“r”, from the reagent cartridge.

19. The reactor apparatus according to claim 17, wherein the reactor apparatus is configured to adjust the carrier gas mass flow rate, “m”⋅\hat{ }“c”, based on at least a first pressure reading indicative of pressure inside the reagent chamber of the reagent cartridge.

20. The reactor apparatus according to claim 17, wherein the reactor apparatus is further configured to detect formation of a blockage downstream from the reagent cartridge based on at least part of the at least one cartridge pressure reading.

21. The reactor apparatus according to claim 20, wherein the reactor apparatus is further configured to detect the formation of the blockage based on at least a second pressure reading indicative of pressure inside a gas ejection chamber of the reagent cartridge.

22. The reactor apparatus according to claim 17, wherein the reactor apparatus is further configured to produce carbon-based high-aspect-ratio molecular structures, HARMSs, such as carbon nanotubes, e.g., single-walled carbon nanotubes and/or multi-walled carbon nanotubes; and/or carbon nanobuds; and/or graphene nanoribbons; and/or graphite nanoribbons; and/or carbon nanofibers; and/or graphene nanoplatelets.

22. The reactor apparatus according to claim 17, wherein the reagent cartridge is further configured to form a reagent-carrier gas mixture comprising one or more catalyst particle precursors, e.g., iron-containing organometallic or metalorganic compounds, such as ferrocene (Fe(C5H2)2), iron pentacarbonyl (Fe(CO)5), and/or iron (II) phthalocyanine (C32H16FeN8); and/or one or more nickel-containing organometallic or metalorganic compounds, such as nickelocene (Ni(C5H5)2); and/or one or more cobalt-containing organometallic or metalorganic compounds, such as cobaltocene (Co(C5H5)2), as the reagent gas.

23. A reactor apparatus comprising a reagent cartridge for holding a reagent cartridge according to claim 15, wherein during operation of the reactor apparatus, the reactor apparatus being configured to receive from at least one pressure sensor of the reagent cartridge at least one cartridge pressure reading indicative of pressure inside the reagent cartridge, the reactor apparatus being further configured to receive from the first temperature sensor a first temperature reading indicative of temperature inside the reagent chamber and from the second temperature sensor a second temperature reading indicative of temperature inside the gas injection chamber.

24. The reactor apparatus according to claim 23, wherein the reactor apparatus is further configured to maintain a pre-determined solid reagent temperature, “T”\hat{ }“r”, based on at least the first temperature reading and the second temperature reading.

25. The reactor apparatus according to claim 23, wherein the reactor apparatus further comprises a cartridge heater for heating the reagent cartridge and a pre-heater for heating the carrier gas upstream of the reagent cartridge, and the reactor apparatus is configured to:
adjust pre-heater temperature, “T”\hat{ }“ph”, based on a comparison between the solid reagent temperature, “T”\hat{ }“r”, and the second temperature reading; and
adjust cartridge heater temperature, “T”\hat{ }“ch”, based on a comparison between the solid reagent temperature, “T”\hat{ }“r”, and the first temperature reading.

26. The reactor apparatus according to claim 23, wherein the reactor apparatus further comprises a reagent gas conduit for extracting reagent-carrier gas mixture from the reagent cartridge and a reagent conduit heater for heating the reagent gas conduit.
